(19) United States
(12) Patent Application Publication
(10) Pub. No.: US 2008/0151954 A1
(43) Pub. Date: Jun. 26, 2008

(54) Nd:YV04 laser crystal and method of growth and use thereof

(75) Inventors: Kelvin G. Lynn, Pullman, WA (US); Elgin E. Eissler, Renfrew, PA (US); Xiaoming Li, Allison Park, PA (US)

Correspondence Address: THE WEBB LAW FIRM, P.C., 700 KOPPERS BUILDING, 436 SEVENTH AVENUE, PITTSBURGH, PA, 15219, US

(73) Assignee: II-VI Incorporated, Saxonburg, PA (US)

(21) Appl. No.: 11/827,608

(22) Filed: Jul. 12, 2007

Related U.S. Application Data
(60) Provisional application No. 60/830,362, filed on Jul. 12, 2006.

(51) Int. Cl. H01S 3/16; C01F 17/00; C30B 15/00

(52) U.S. Cl. 372/41; 117/73; 117/13; 423/263

(57) ABSTRACT

In a method of forming an Nd:YVO₄ laser crystal, a melt of Nd:YVO₄ in a vacuum is provided and an Nd:YVO₄ seed crystal is provided in the vacuum with its c-axis oriented perpendicular to a surface of the melt. While in the vacuum, Nd:YVO₄ from the melt is caused to adhere to the Nd:YVO₄ seed crystal thereby forming an Nd:YVO₄ boule with its c-axis oriented perpendicular to the surface of the melt. A portion of the boule can be removed therefrom to become an Nd:YVO₄ laser crystal having no sub-grain boundaries and/or ghost veils in a cross section thereof perpendicular to the c-axis. This c-axis grown Nd:YVO₄ crystal can be used as the lasing element of a laser.

### CROSS REFERENCE TO RELATED APPLCIATION

The present application claims priority from U.S. Provisional Patent Application No. 60/830,362, filed on Jul. 12, 2006, entitled “Nd:YVO₄ Laser Crystal And Method Of Growth And Use Thereof”, the contents of which are incorporated herein by reference.

### STATEMENT REGARDING FEDERALLY SPONSORED RESEARCH AND DEVELOPMENT

The U.S. Government has a paid-up license in this invention and the right in limited circumstances to require the patent owner to license others on reasonable terms as provided for by the terms of contract No. N66001-00-C-6008 awarded by the Department of Defense, Joint Electromagnetics Technology Program Office and by the terms of contract No. DE-FG02-04ER46103 awarded by the Department of Energy.

### BACKGROUND OF THE INVENTION

1. Field of the Invention

The present invention relates to monocrystalline or single crystal Nd:YVO₄ laser crystals, a method of growth thereof and a laser incorporating a monocrystalline or single crystal Nd:YVO₄ laser crystal.

2. Description of Related Art

Diode-pumped, solid-state lasers are one of the most promising approaches in high-power lasers. It is well-known that neodymium doped, yttrium otrhovanadate (Nd:YVO₄) is a desirable material from which to form solid-state lasers useful in the fields of industry, defense, and medical surgery. Nd:YVO₄ has a low pumping threshold, large emission section, large absorption coefficient, broad absorption bandwidth, and exceptional mechanical and physical properties. However, it is difficult to obtain Nd:YVO₄ crystals that do not include defects that limit the output power of lasers incorporating such crystals. While many methods of growing Nd:YVO₄ crystals have been explored, the Czochralski method has proven to be the most successful in the avoidance of defects, including, without limitation, inclusions, partial layer substructures, and other lattice defects. Notwithstanding, it would be desirable to grow Nd:YVO₄ crystals having even less (or fewer) defects than Nd:YVO₄ crystals grown in accordance with prior art growth methods.

Accordingly, what is needed is a method of growing Nd:YVO₄ crystals that further avoids the formation of defects therein commonly found in Nd:YVO₄ crystals grown in accordance with prior art methods. What is also need is an Nd:YVO₄ crystal that has less defects than prior art Nd:YVO₄ crystals. Still further, what is needed is a laser formed from an Nd:YVO₄ crystal which has less defects. Still other needs that the present invention overcomes will become apparent to those of ordinary skill in the art upon reading and understand the following detailed description.

### SUMMARY OF THE INVENTION

The invention is a method of forming an Nd:YVO₄ laser crystal. The method includes providing a melt of Nd:YVO₄ in a vacuum or the presence of a suitable pressure inert gas, such as, without limitation, Argon, and providing an Nd:YVO₄ seed crystal in the vacuum or in the presence of the inert gas with its c-axis oriented perpendicular to a surface of the melt. While in the vacuum or in the presence of the inert gas, Nd:YVO₄ from the melt is caused to adhere to the Nd:YVO₄ seed crystal thereby forming an Nd:YVO₄ boule with its c-axis oriented perpendicular to the surface of the melt.

The method can further include removing from the boule a portion thereof, wherein the removed portion of the boule comprises an Nd:YVO₄ laser crystal.

The melt can include between 0.2 and 3 atomic percent of Nd. Also or alternatively, the melt can include an approximately stoichiometric mixture of YVO₄.

The Czochralski method can be utilized to cause Nd:YVO₄ from the melt to adhere to the Nd:YVO₄ seed crystal.

The invention is also a c-axis grown Nd:YVO₄ laser crystal having no sub-grain boundaries and ghost veils in a cross section thereof perpendicular to the c-axis, wherein the concentration of Nd in the crystal is between 0.2 and 6 atomic percent, and wherein a ghost veil is defined as a non-mobile tilt boundary created and locked in by the interaction of dislocations in the crystal that can be seen only under suitable lighting and crystal orientation.

Lastly, the invention is an Nd:YVO₄ laser that includes a c-axis grown Nd:YVO₄ crystal and means for outputting at least one first ray or beam of electromagnetic radiation to the crystal, whereupon, in response to the first beam of electromagnetic radiation impinging thereon, the crystal outputs a second ray or beam of electromagnetic radiation having a frequency different than a frequency of the first ray or beam. The laser also includes means for reflecting the second ray or beam to-and-fro along a path that includes the crystal and for passing the second ray or beam when it has attained sufficient intensity in response to reflecting to-and-fro along the path.

The first ray or beam is desirably input into the crystal perpendicular to its c-axis and parallel to one of the crystal's a-axes. The second ray or beam is desirably output by the crystal parallel to the first ray or beam.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

FIG. 1 is a diagrammatic cross section of an apparatus for growing an Nd:YVO₄ boule in accordance with the present invention;

FIG. 2 is a diagram of a portion of the boule shown in FIG. 1 grown in accordance with the method of the present invention utilizing the apparatus of FIG. 1;

FIG. 3(a) is an open view of a laser cavity housing the components comprising an exemplary laser;

FIG. 3(b) is a close-up view of the Nd:YVO₄ crystal and the two laser diode assemblies of the laser shown in FIG. 3(a);

FIG. 4 is a diagram of another exemplary laser that uses a different arrangement of the components of the laser shown in FIG. 3(a);

FIG. 5 is a plot of average output power vs. input power plot for a-axis and c-axis grown laser crystals with various output couplers R;

FIG. 6 is a diagrammatic illustration of a cross-polarization arrangement for taking optical microscope photographs of a-axis and c-axis grown laser crystals;

FIG. 7 is a plot of average output power vs. input power for a-axis and c-axis grown laser crystals with an 85% output coupler R;

FIG. 8(a) is a computer enhanced optical microscope photo using cross-polarization of a section of a 0.27% Nd:YVO₄ a-axis grown boule;

FIG. 8(b) is a computer enhanced optical microscope photo using cross-polarization of a section of a 0.27% Nd:YVO₄ c-axis grown boule;

FIG. 9(a) is a computer enhanced optical microscope photo using cross polarization of a section of an undoped YVO₄ a-axis grown boule;

FIG. 9(b) is a computer enhanced optical microscope photo using cross polarization of a section of an undoped YVO₄ c-axis grown boule;

FIG. 10 is a photo of an a-axis grown 1.0% Nd:YVO₄ boule showing discoloration in the middle area thereof as a result of precipitates, scatter centers, and/or microscopic thermal stress fractures;

FIG. 11 is an unpolarized optical microscope photo of a group of ghost veils in a section of an a-axis grown Nd:YVO₄ boule;

FIG. 12(a) is a computer enhanced optical microscope photo using cross-polarization of a section of an a-axis grown 0.27% Nd:YVO₄ crystal, wherein sub-grain boundaries are visible on the left and right parts of the crystal and the bright spot is a reflection from the camera taking the picture; and

FIG. 12(b) is a computer enhanced optical microscope photo using cross-polarization of a section of a c-axis grown 0.27% Nd:YVO₄ crystal having no sub-grain boundaries.

### DETAILED DESCRIPTION OF THE INVENTION

An embodiment of the present invention will now be described with reference to the accompanying figures where like reference number correspond to like elements.

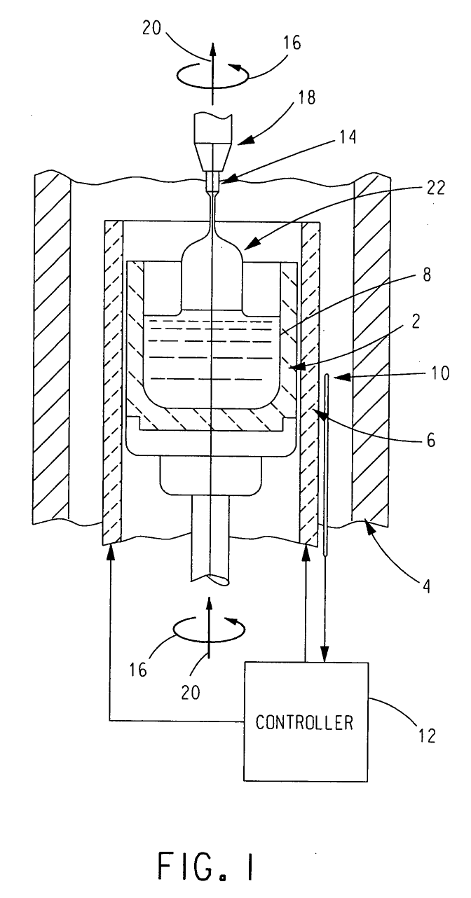

With reference to FIG. 1, a method of growing an Nd:YVO₄ crystal or boule utilizing the Czochralski method will now be described. The description of the Czochralski method to grow the Nd:YVO₄ crystal or boule, however, is not to be construed as limiting the invention since it is envisioned that any other suitable and/or desirable grown method known to those skilled in the art can be utilized to grow the Nd:YVO₄ crystal or boule.

In the Czochralski method, a crucible 2 is positioned in a vessel 4 having one or more heaters 6 operatively positioned therein for heating the interior of vessel 4 such that a material 8 disposed in crucible 2 melts. Desirably, a thermocouple 10 is positioned inside vessel 4 for detecting the temperature therein and for providing an indication of the detected temperature to a controller 12 which is operatively connected to heater(s) 6 for controlling the operation thereof in a manner known in the art such that the inside of vessel 4 is maintained at a desired temperature sufficient to melt material 8 and to maintain material 8 in its melted state. Material 8 in its melted state inside of crucible 2 is also known as a so-called “melt”. In a preferred embodiment, the melt includes a stoichiometric, or near stoichiometric, mixture of YVO₄ and between 0.2 and 3 atomic percent of Nd. However, this is not to be construed as limiting the invention since it is envisioned that the melt can be comprised of any suitable and/or desirable mixture of YVO₄ and/or suitable and/or desirable percentage of Nd.

At a suitable time after the melt is formed, an Nd:YVO₄ seed crystal 14 is positioned just at the surface of the melt via a seed holder 18. In order to grow an Nd:YVO₄ crystal or boule as perfect and free from imperfections as possible, Nd:YVO₄ seed crystal 14 is slowly rotated or turned about an axis that extends substantially normal to the surface of the melt in the direction shown by arrows 16 (or in the opposite direction) via seed holder 18 as Nd:YVO₄ seed crystal 14 is slowly drawn away from the surface of the melt in the direction shown by arrows 20. In response to simultaneously rotating Nd:YVO₄ seed crystal 14 in the direction shown by arrows 16 (or in the opposite direction) and drawing Nd:YVO₄ seed crystal 14 away from the surface of the melt in the direction shown by arrows 20, material from the melt condenses on Nd:YVO₄ seed crystal 14 thereby forming an Nd:YVO₄ boule 22.

In contrast to prior art methods of growing an Nd:YVO₄ boule along one of its a-axes via any growth method known in the art, especially the Czochralski method, Nd:YVO₄ seed crystal 14 is oriented with its c-axis parallel, or substantially parallel, to the direction shown by arrows 20, whereupon boule 22 grows along its c-axis.

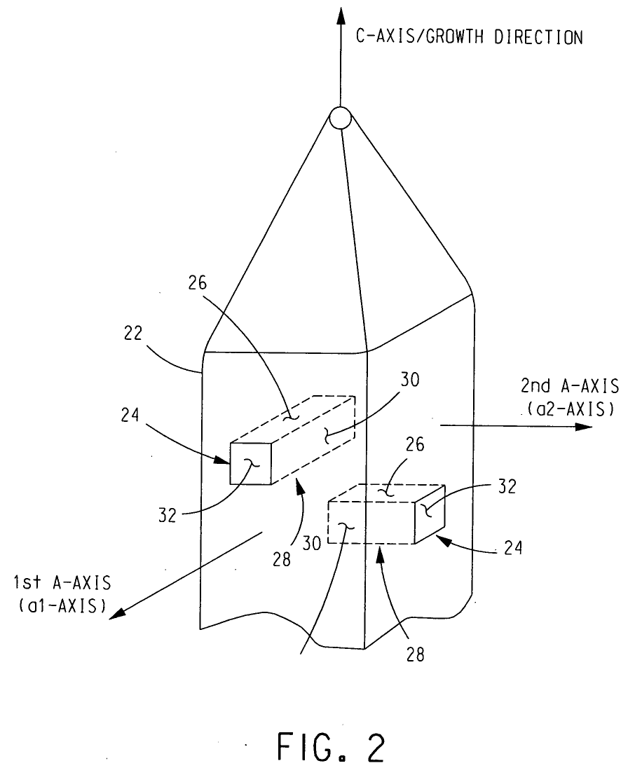

With reference to FIG. 2 and with continuing reference to FIG. 1, once boule 22 has been formed, it is removed from vessel 4. Thereafter, utilizing one or more suitable techniques known in the art, one or more rods 24 of Nd:YVO₄ crystal, desirably parallelepiped-shaped, are cut from boule 22. Desirably, each rod 24 is formed by making a number of cuts in boule 22 perpendicular to its c-axis to define the top and bottom faces 26 and 28, respectively, of rod 24 and the side faces 30 of rod 24. Boule 22 may also be cut. as needed, parallel to the c-axis of boule 22 to define each end face 32 of rod 24.

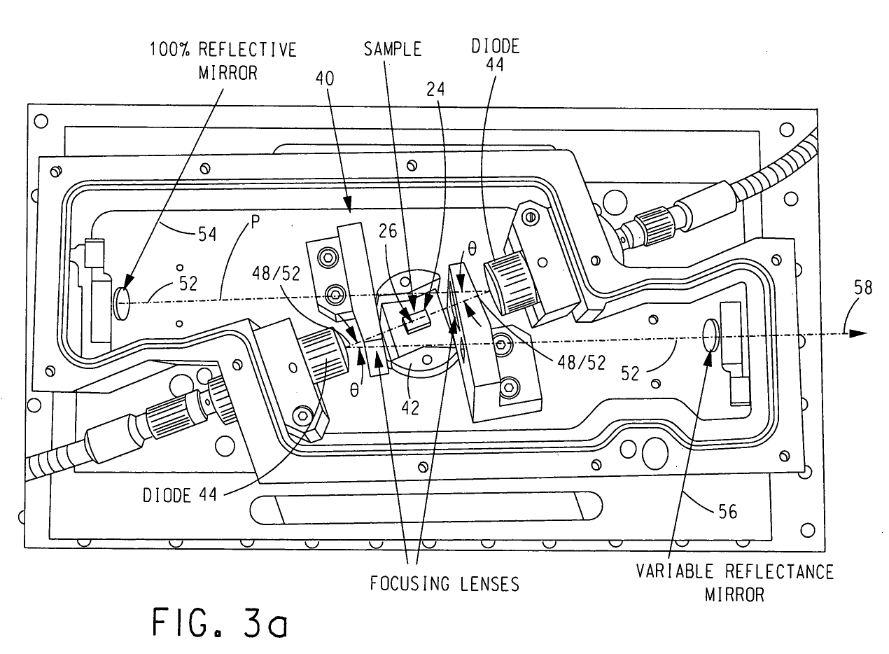

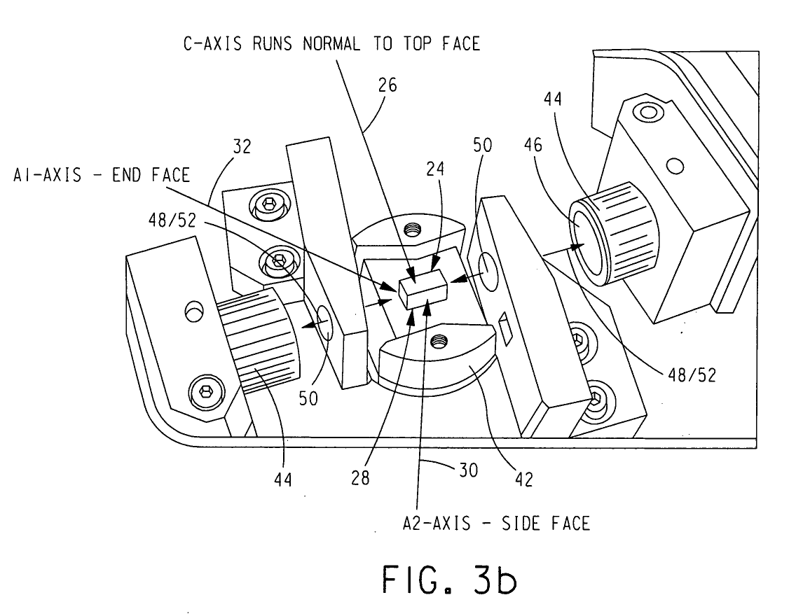

With reference to FIGS. 3(a) and 3(b) and with continuing reference to FIGS. 1 and 2, once rod 24 has been cut from boule 22 and any further processing of rod 24 has been accomplished (e.g., polishing of one or more faces of rod 24), it may be incorporated into a laser, such as exemplary z-shaped laser 40. Laser 40 includes rod 24 with its bottom face 28 coupled to a heat sink assembly 42 and with its end faces 32 positioned facing the outputs of laser diode assemblies 44 positioned on either end of rod 24. Each laser diode assembly 44 includes a reflector 46 on the output thereof for passing to one end face 32 of rod 24 a first wavelength (e.g., 808 nm) ray or beam of electromagnetic radiation or laser light 48 generated by an internal laser diode (not shown) of assembly 44. Laser light 48 passing through each reflector 46 passes through a focusing lens 50 before impinging on one of the end faces 32 of rod 24.

In response to being “pumped” on one or both of its end faces 32 with laser light 48 from one or both laser diode assemblies 44 in a manner known in the art, rod 24 generates a second wavelength (e.g., 919 nm, 1064 nm or 1342 nm) ray or beam of electromagnetic radiation or laser light 52 that exits the end faces 32 of rod 24 parallel to laser light 48. Laser light 52 exiting the end faces 32 of rod 24 traverses a path P (shown in phantom in FIG. 3(a)) that includes focusing lens 50, the exterior surfaces of reflectors 46 which reflect laser light 52 at an angle θ, a fully reflective mirror 54, a partially reflective mirror (or output coupler) 56 and rod 24, which further amplifies the intensity of laser light 52 reflected by either mirror 54 or 56 in response to being pumped with laser light 48.

The combination of mirrors 54 and 56 and one or both laser diode assemblies 44 pumping rod 24 with laser light 48 coact to cause laser light 52 to pass to-and-fro along path P between mirrors 54 and 56 until laser light 52 has attained sufficient intensity to pass through mirror 56. In FIG. 3(a), laser light 52 that has passed through mirror 56 is denoted by the reference number 58.

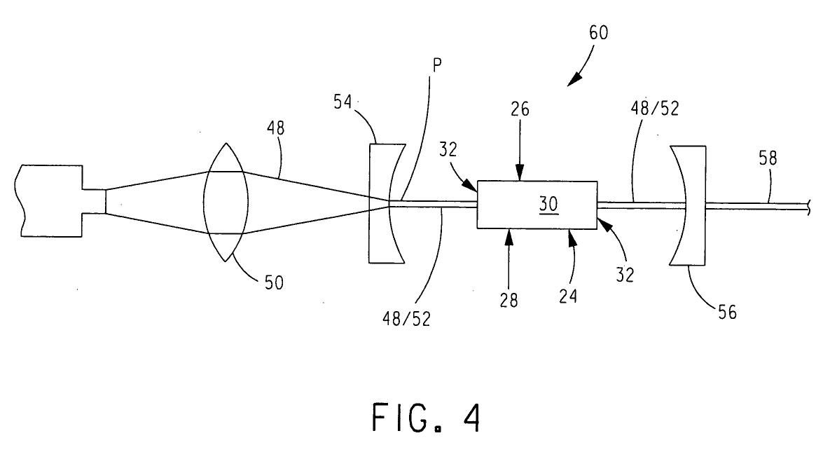

With reference to FIG. 4 and with continuing reference to FIGS. 1-3(b), another exemplary laser 60 includes rod 24, mirrors 54 and 56, a single focusing lens 50 and a single laser diode assembly 44 all arranged as shown. In exemplary laser 60, mirror 54 is configured to pass laser light 48 emanating from laser diode assembly 44 to rod 24 but to fully reflect laser light 52 emanating from rod 24. Like mirrors 54 and 56 of laser 40, mirrors 54 and 56 of laser 60 reflect laser light 52 to-and-fro along a path P that runs between mirrors 54 and 56 and through rod 24 until laser light 52 has attained sufficient intensity to pass through mirror 56. In FIG. 4, laser light 52 that has passed through mirror 56 is denoted by the reference number 58.

Lasers 40 and 60 are shown to illustrate how a c-axis grown Nd:YVO₄ crystal, i.e., rod 24, can be used therein and are not to be construed as limiting the invention.

Experiments:

To verify the novel and non-obvious benefit of a c-axis grown Nd:YVO₄ crystal versus an a-axis grown Nd:YVO₄ crystal, two experiments were performed.

The first experiment measured the output power measurement of a- and c-axis grown (approximately 0.27% Nd) Nd:YVO₄ crystals. Four (4) a-cut, c-axis grown Nd:YVO₄ crystals and four (4) a-cut, a-axis grown crystals were selected for analysis. All crystals were 4×4×8 mm in dimension. The four c-axis grown crystals were determined to be of fairly good quality, and the four a-axis grown crystals were characterized as benchmark samples. Each crystal was incorporated into a laser, like laser 40 or 60, and oriented therein in the manner described above and shown in FIGS. 3(a) and 3(b), and “pumped” from both ends by laser diode assemblies, like laser diode assemblies 44 of laser 40, having center wavelengths of 808 nm.

The temperature of the laser diode of each diode assembly was controlled to 24 degrees Celsius to maximize the output power of each crystal. Five output couplers (R), each like mirror 56 in FIG. 3(b), ranging in reflectance from 75%±5% to 94%±5% were selected for this experiment.

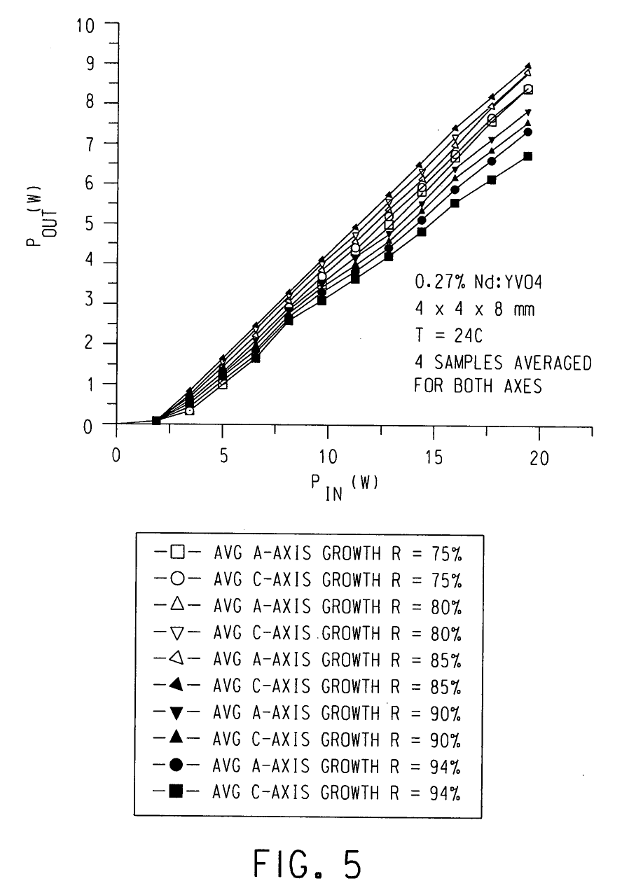

The average output power versus input power for each crystal grown axis was then obtained for each output coupler R. Data was taken this way for over a year with several changes implemented to the laser. These changes included: replacement of the output couplers R, replacement of the 100% reflectance back mirror (like mirror 54), optimization of the laser diodes, and realignment of the laser mirrors (like mirrors 54 and 56) for maximum output power. FIG. 5 shows a plot of average output power versus input power for each crystal grown axis and each output coupler R.

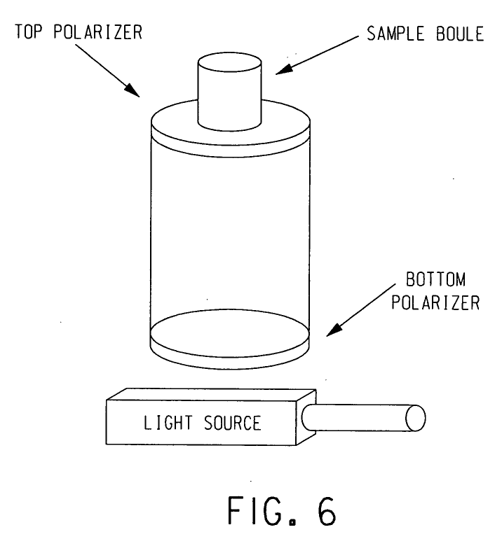

In the second experiment, an optical microscope was used to find macroscopic defects within several a- and c-axis grown boules. Cross-polarization was utilized to indicate the presence of sub-grain boundaries. FIG. 6 shows an exemplary polarization arrangement that was used to find the macroscopic defects.

In industry, a so-called “veil” is defined as any light scattering defect in the bulk of the crystal. Thermal stress fractures, voids, sub-grain boundaries, dislocations, and tilt boundaries are all included in the broad definition of “veil”. Herein, a “veil” is further defined as a non-mobile tilt boundary created and locked in by the interaction of dislocations in the crystal. Veils have the appearance of wide mesh defects that create the facade of a cloth veil within the bulk of the crystal. Herein, a veil that can only be seen under correct lighting and crystal orientation is known as a ghost veil.

Results:

The following Table 1 shows the average slope efficiency for each grown axis for each output coupler. The slope efficiencies are slightly above 50% for the 75%, 80%, and 85% reflectivity output couplers. However, as the reflectivity increases above 85%, slope efficiency decreases.

TABLE 1
Average slope efficiencies for various output couplers.

| Output coupler | a-axis grown average | c-axis grown average |
|---|---|---|
| reflectance | slope efficiency | slope efficiency |
| (%) | (%) | (%) |
| 75 | 51.1 +/− 0.3 | 50.9 +/− 0.1 |
| 80 | 51.7 +/− 0.3 | 51.1 +/− 0.2 |
| 85 | 51.6 +/− 0.4 | 51.5 +/− 0.2 |
| 90 | 45.3 +/− 0.1 | 43.8 +/− 0.2 |
| 94 | 41.5 +/− 0.3 | 37.4 +/− 0.3 |

The following Table 2 shows the average maximum output power obtained for each output coupler and grown axis. In Table 2, the average slope efficiencies of the 75%, 80%, and 85% reflectivity output couplers are roughly comparable within the error of the measurement. However, for the 90% and 94% reflectivity output couplers, a-axis grown crystals produced, on average, a more efficient and powerful laser beam. The maximum average output power obtained for both crystal grown directions was achieved with the 85% output coupler and was higher for the c-axis grown crystals than the a-axis grown crystals, which were considered benchmark samples.

TABLE 2
Maximum average output power for various output couplers.
All values for output powers have errors of +/−0.03 W.

| Output coupler | a-axis grown max. avg. | c-axis grown max. |
|---|---|---|
| reflectance | output power | avg. output power |
| (%) | (W) | (W) |
| 75 | 8.48 | 8.50 |
| 80 | 8.85 | 8.82 |
| 85 | 8.88 | 8.99 |
| 90 | 7.83 | 7.53 |
| 94 | 7.31 | 6.71 |

Of interest is the actual measured Nd concentration of the samples used in the experiment. The same amount of Nd was added to each melt. However, the measured Nd concentration of the samples varied from this amount. The following Table 3 shows the measured Nd concentrations for the samples used in the experiment.

TABLE 3
Measured Nd concentrations of a-axis and c-axis grown
Nd:YVO₄ laser crystals.

| | | Nd Concentration |
|---|---|---|
| Sample Name | Grown Axis | (%) |
| Sample 1-C | c | 0.31 |
| Sample 2-C | c | 0.32 |
| Sample 3-C | c | 0.30 |
| Sample 4-C | c | 0.30 |
| Sample 1-A | a | 0.23 |
| Sample 2-A | a | 0.24 |
| Sample 3-A | a | 0.26 |
| Sample 4-A | a | 0.26 |

All Nd concentration measurements were taken by x-ray fluorescence spectroscopy. Several measurements for each sample were taken and averaged with a resulting error of 0.05%.

It has been observed that that the measured values of Nd concentration in c-axis grown crystals are higher than the expected amount (0.27%) of Nd concentration. Moreover, since the same amount of Nd was placed in each melt, it was expected that the measured concentrations would be equal for both grown axes. However, the c-axis grown samples have a higher Nd concentration than the a-axis grown ones. It is believed this discrepancy is due to the structure of the crystal. Namely, the two axes are structurally different causing dissimilar incorporations of Nd in its structure. Hence, the Nd segregation coefficient is dependent upon choice of growth axis and results in differing Nd concentrations for the two grown axes.

It has been observed that by proper selection of the Nd concentration in the melt, the concentration of Nd in c-axis grown crystals can be controlled to be between 0.2 and 6 atomic percent. The concentration of 6 atomic percent in c-axis grown Nd:YVO₄ crystals has, heretofore, not been observed in a-axis grown Nd:YVO₄ crystals. Thus, c-axis grown Nd:YVO₄ crystals facilitate a higher concentration of Nd than a-axis grown Nd:YVO₄ crystals.

Discussion

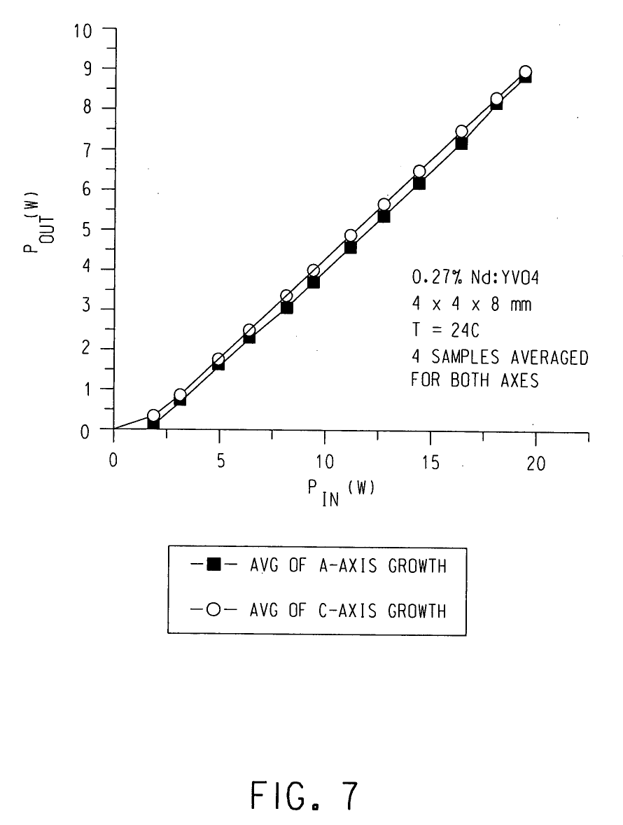

FIG. 7 shows plots of average output power versus input power for crystals grown in both the a-axis and c-axis grown directions when used with an 85% output coupler. Since the 85% output coupler gave the highest average output power for both axes, the plots of FIG. 7 can provide some insight into the cause of the output power difference between the two growth direction axes.

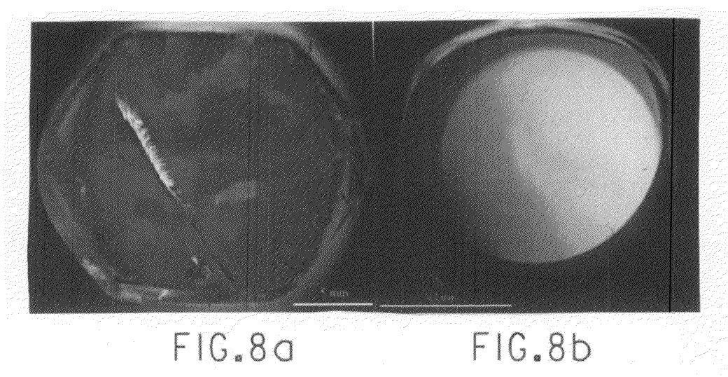

It is believed that the difference in the output power is caused by the presence of sub-grain boundaries and ghost veils in a-axis grown boules. Such defects in c-axis grown boules have not been observed. For example, FIG. 8(a) is a photograph of a 0.27% Nd:YVO₄ a-axis grown and polished boule, and FIG. 8(b) is a photograph of a 0.27% Nd:YVO₄ c-axis grown and polished boule. In FIG. 8(a), there is a high concentration of sub-grain boundaries within the bulk of the boule, whereas in FIG. 8(b) there are no sub-grain boundaries present in the boule.

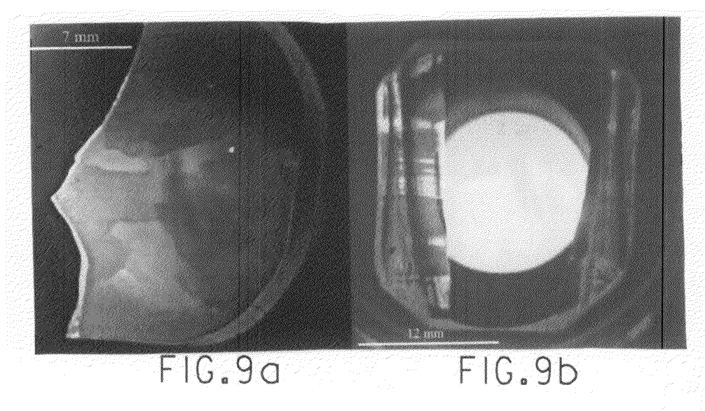

It was originally believed that Nd doping played a role in the creation of the sub-grain boundaries observed in FIG. 8(a). To verify this, two undoped YVO₄ boules were obtained, one c-axis grown and one a-axis grown. Both samples were polished and viewed under a microscope with cross-polarization. FIGS. 9(a) and 9(b) are photographs of the a-axis grown boule and c-axis grown boule, respectively. As can be seen, there are no sub-grain boundaries in the c-axis grown boule of FIG. 9(b), whereas the a-axis grown boule of FIG. 9(a) contains many. It is believed that the sub-grain boundaries in the a-axis grown boule of FIG. 9(a) are the result of the thermodynamic reduction of internal stresses introduced during the grown process. The produced stress(es) is (are) alleviated by the creation of different grains through the slip system of the crystal. It is believed that while these same stresses occur in c-axis grown boules, there is no slip system available for their reduction. Thus, most of the defects that occur in c-axis grown boules are the result of thermal fracture and internal stress fracture introduced by the grown process. However, these defects can be reduced or eliminated with careful control of the grown process.

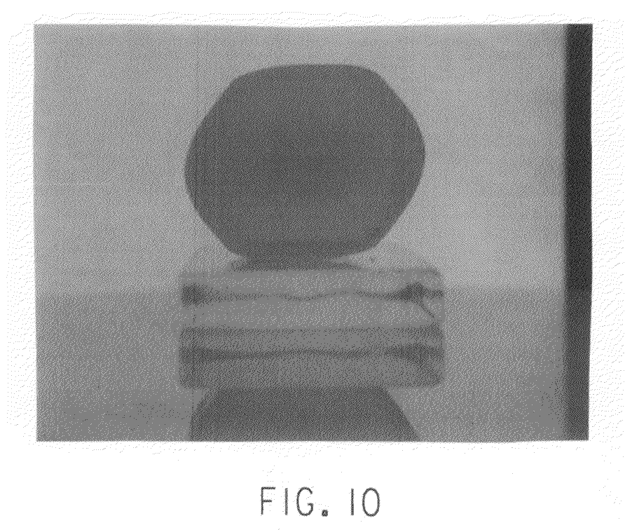

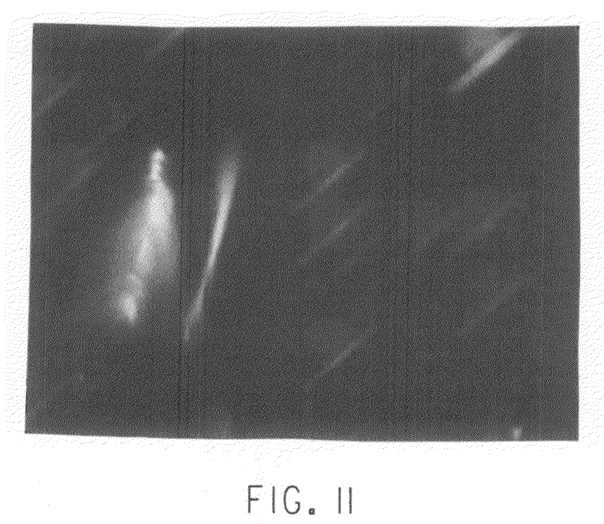

In addition to sub-grain boundaries, a-axis grown boules also contain light scatters and ghost veils. FIG. 10 is an end view photograph of a 1.0% Nd:YVO₄ a-axis grown boule 70. Light scatter centers can be seen in the middle area of boule 70. These light scatter centers have been found in both a-axis grown and c-axis grown boules and are caused by precipitates as well as microscopic thermal fractures formed during the grown process. However, so-called ghost veils have only been found in a-axis grown boules. FIG. 11 is a photograph of an area of an a-axis grown boule containing many ghost veils. Although they are very difficult to find in a boule, they do not require cross-polarization to locate. Ghost veils scatter light and reduce the quality of the produced laser beam. It is believed that there is a correlation between the presence of sub-grain boundaries and the presence of ghost veils in a-axis grown boules. Specifically, it is believed that ghost veils are concentrated along sub-grain boundary edges in a-axis grown boules and are scarce in regions of single grains.

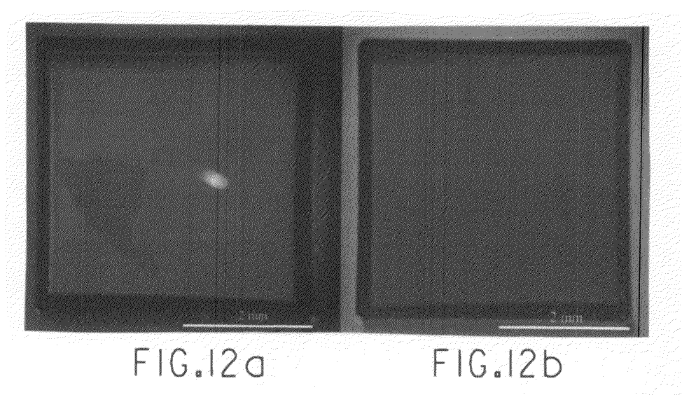

Care must be taken when selecting regions of the boule to cut into laser crystals. Choosing regions with grain boundaries can inhibit its performance as a laser crystal. FIG. 12(a) is a photograph of one of the a-axis grown laser crystals used in this experiment. Because the laser diode assemblies used in the experiment only pump an area of 1 mm², it is possible to cut an a-axis grown Nd:YVO₄ crystal such that it does not have any sub-grain boundaries in the pumping path. However, this is not an issue for c-axis grown Nd:YVO₄ crystals. FIG. 12(b) is a photograph of one of the c-axis grown Nd:YVO₄ crystals used in the experiment. No sub-grain boundaries are visible in this crystal which could inhibit its performance as a laser crystal. This was the general trend for all the c-axis grown Nd:YVO₄ crystals used in the experiment.

### CONCLUSION

Structural defects in single crystals such as sub-grain boundaries, veils, and scatter centers reduce the performance of the laser. Thus, in order to obtain the highest output power of a laser, defects in the crystal must be minimized. One way to accomplish this is by selecting a suitable grown axis that contains no such defects. There is a physical difference between a-axis and c-axis grown crystals, and this difference is significant enough to observe an output power difference between the two grown directions. From the data, it was shown that properly grown c-axis grown crystals, containing no veils, and sub-grain boundaries, are more suited for higher output power applications than a-axis grown crystals which can contain such defects.

The invention has been described with reference to the preferred embodiment. Obvious modifications and alterations will occur to others upon reading and understanding the preceding detailed description. It is intended that the invention be construed as including all such modifications and alterations insofar as they come within the scope of the appended claims or the equivalents thereof.

The invention claimed is:

1. A method of forming an Nd:YVO₄ laser crystal comprising:
(a) providing a melt of Nd:YVO₄;
(b) providing an Nd:YVO₄ seed crystal with its c-axis oriented perpendicular to a surface of the melt; and
(c) causing Nd:YVO₄ from the melt to adhere to the Nd:YVO₄ seed crystal thereby forming an Nd:YVO₄ boule with its c-axis oriented perpendicular to the surface of the melt.

2. The method of claim 1, wherein the melt includes between 0.2 and 3 atomic percent of Nd.

3. The method of claim 1, wherein the melt includes approximately a stoichiometric mixture of YVO₄.

4. The method of claim 1, wherein step (c) is accomplished via the Czochralski method.

5. The method of claim 1, further including removing from the boule a portion thereof, wherein the removed portion of the boule comprises an Nd:YVO₄ laser crystal.

6. A c-axis grown Nd:YVO₄ laser crystal having no sub-grain boundaries and/or ghost veils in a cross section thereof perpendicular to the c-axis, wherein the concentration of Nd in the crystal is between 0.2 and 6 atomic percent.

7. The crystal of claim 6, wherein a ghost veil is a non-mobile tilt boundary created and locked in by the interaction of dislocations in the crystal that can be seen only under suitable lighting and crystal orientation.

8. An Nd:YVO₄ laser comprising:
a c-axis grown Nd:YVO₄ crystal;
means for outputting at least one first ray or beam of electromagnetic radiation to the crystal, whereupon, in response thereto, the crystal outputs a second ray or beam of electromagnetic radiation having a frequency different than a frequency of the first ray or beam; and
means for reflecting the second ray or beam to-and-fro along a path that includes the crystal and for passing the second ray or beam when it has attained sufficient intensity in response to reflecting to-and-fro along the path.

9. The laser of claim 8, wherein the first ray or beam is input into the crystal perpendicular to its c-axis and parallel to one of the crystal's a-axes.

10. The laser of claim 9, wherein the second ray or beam is output by the crystal parallel to the first ray or beam.
